(19) United States
(12) Patent Application Publication
(10) Pub. No.: US 2025/0139320 A1
(43) Pub. Date: May 1, 2025

(54) SYSTEMS AND METHODS FOR AN ASYNCHRONOUS FLIGHT COMPUTER SIMULATOR

(71) Applicant: The Boeing Company, Arlington, VA (US)

(72) Inventors: Amir Leon Liaghati, Irvine, CA (US); Eric B. Delmonico, Huntsville, AL (US); Charles Muwonge, Huntsville, AL (US)

(73) Assignee: The Boeing Company, Arlington, VA (US)

(21) Appl. No.: 18/636,600

(22) Filed: Apr. 16, 2024

Related U.S. Application Data
(60) Provisional application No. 63/594,307, filed on Oct. 30, 2023.

(51) Int. Cl. G06F 30/15

(52) U.S. Cl. CPC G06F 30/15

(57) ABSTRACT

A method, computer program product, and computer system for identifying, by a computing device, a plurality of information associated with a flight simulation. A plurality of charts for a plurality of frame arrivals can be initialized based upon, at least in part, the plurality of information associated with the flight simulation. The plurality of charts can be populated based upon, at least in part, a portion of the plurality of information associated with the flight simulation. At least a portion of the plurality of charts can be combined together. A total amount of bandwidth needed for the flight simulation can be predicted based upon, at least in part, the combining together at least the portion of the plurality of charts.

This application claims the benefit of U.S. Provisional Application No. 63/594,307, filed on 30 Oct. 2023, the contents of which are all incorporated by reference.

The invention described herein was made in the performance of work under NASA Contract No. (NNM07AB03C) and is subject to the provisions of Section 305 of the National Aeronautics and Space Act of 1958 (72 Stat. 435: 42 U.S.C. 2457.)

### BACKGROUND

Generally, qualification of test data is one of the key parts of validation, which requires a lot of planning, cost and effort. To test and analyze certain systems that are multiplexed together then transmitted to ground, involves creating procedures, releasing documents, labor to install all components, executing tests, analyzing test data, and documenting results, while potentially under aggressive timeline to complete all tasks.

### SUMMARY

In one example implementation, a method, performed by one or more computing devices, can include but is not limited to identifying, by a computing device, a plurality of information associated with a flight simulation. A plurality of charts for a plurality of frame arrivals can be initialized based upon, at least in part, the plurality of information associated with the flight simulation. The plurality of charts can be populated based upon, at least in part, a portion of the plurality of information associated with the flight simulation. At least a portion of the plurality of charts can be combined together. A total amount of bandwidth needed for the flight simulation can be predicted based upon, at least in part, the combining together at least the portion of the plurality of charts.

One or more of the following example features can be included. Populating the plurality of charts can include updating a final chart of the plurality of charts. At least some of the portion of the plurality of information associated with the flight simulation can be simulated using an actual load used for a flight when one or more portions of the plurality of information associated with the flight simulation is unavailable. The plurality of charts can include a number of message identifier headers per frame. The plurality of charts can be classified based on virtual identifications (ID). The plurality of information associated with the flight simulation can include content ID, frame length, frequency of occurrence, description, frame starting, virtual channel ID, or combinations thereof. At least a portion of the plurality of charts can be updated for each content ID.

In another example implementation, a computing system can include one or more processors and one or more memories configured to perform operations that can include but are not limited to identifying, by a computing device, a plurality of information associated with a flight simulation. A plurality of charts for a plurality of frame arrivals can be initialized based upon, at least in part, the plurality of information associated with the flight simulation. The plurality of charts can be populated based upon, at least in part, a portion of the plurality of information associated with the flight simulation. At least a portion of the plurality of charts can be combined together. A total amount of bandwidth needed for the flight simulation can be predicted based upon, at least in part, the combining together at least the portion of the plurality of charts.

One or more of the following example features can be included. Populating the plurality of charts can include updating a final chart of the plurality of charts. At least some of the portion of the plurality of information associated with the flight simulation can be simulated using an actual load used for a flight when one or more portions of the plurality of information associated with the flight simulation is unavailable. The plurality of charts can include a number of message identifier headers per frame. The plurality of charts can be classified based on virtual identifications (ID). The plurality of information associated with the flight simulation can include content ID, frame length, frequency of occurrence, description, frame starting, virtual channel ID, or combinations thereof. At least a portion of the plurality of charts can be updated for each content ID.

In another example implementation, a computer program product can reside on a computer readable storage medium having a plurality of instructions stored thereon which, when executed across one or more processors, can cause at least a portion of the one or more processors to perform operations that can include but are not limited to identifying, by a computing device, a plurality of information associated with a flight simulation. A plurality of charts for a plurality of frame arrivals can be initialized based upon, at least in part, the plurality of information associated with the flight simulation. The plurality of charts can be populated based upon, at least in part, a portion of the plurality of information associated with the flight simulation. At least a portion of the plurality of charts can be combined together. A total amount of bandwidth needed for the flight simulation can be predicted based upon, at least in part, the combining together at least the portion of the plurality of charts.

One or more of the following example features can be included. Populating the plurality of charts can include updating a final chart of the plurality of charts. At least some of the portion of the plurality of information associated with the flight simulation can be simulated using an actual load used for a flight when one or more portions of the plurality of information associated with the flight simulation is unavailable. The plurality of charts can include a number of message identifier headers per frame. The plurality of charts can be classified based on virtual identifications (ID). The plurality of information associated with the flight simulation can include content ID, frame length, frequency of occurrence, description, frame starting, virtual channel ID, or combinations thereof. At least a portion of the plurality of charts can be updated for each content ID.

The details of one or more example implementations are set forth in the accompanying drawings and the description below. Other possible example features and/or possible example advantages will become apparent from the description, the drawings, and the claims. Some implementations cannot have those possible example features and/or possible example advantages, and such possible example features and/or possible example advantages can not necessarily be required of some implementations.

### BRIEF DESCRIPTION OF THE DRAWINGS

FIG. 1 is an example diagrammatic view of a simulator process coupled to an example distributed computing network according to one or more example implementations of the disclosure;

FIG. 2 is an example diagrammatic view of a client electronic device of FIG. 1 according to one or more example implementations of the disclosure;

FIG. 3 is an example flowchart of a simulator process according to one or more example implementations of the disclosure; and

FIG. 4 is an example flowchart of a simulator process according to one or more example implementations of the disclosure.

Like reference symbols in the various drawings can indicate like elements.

### DESCRIPTION

Generally, qualification of test data is one of the key parts of validation, which requires a lot of planning, cost and effort. To test and analyze certain systems that are multiplexed together then transmitted to ground, involves creating procedures, releasing documents, labor to install all components, executing tests, analyzing test data, and documenting results, while potentially under aggressive timeline to complete all tasks.

In addition, there can be many permutations of data rates, formats, word size, frame size (e.g., minor frame size), etc. within data containers (e.g., boxes), and if those inputs change, the overall performance after going through the telemetry box (including overall data and overall overhead) needs to be measured each time. To validate, each time there is a change in format, a test has to be performed, which is a significant amount of effort. Moreover, each time a box design changes, the box owner may not know the impact to the overall data and overhead after it is transmitted to the telemetry unit, which can be important in designing an efficient telemetry unit.

In addition, some flight software may differ from that of the software that represents the flight computer's data transmissions. There may also be different software used when performing qualification testing for an avionics telemetry system. One example and non-limiting drawback with certain methods can be a much lesser bandwidth than the flight software's bandwidth that is used in a vehicle, which can be an integral piece to the full bandwidth assessment. For example, the actual flight software used for core stage testing can use more Content IDs with about twice as much data. As a result, to decode the operational flight instrumentation data, the qualification test does not necessarily include all the operational flight instrumentation data transmitted, and estimates are made to compensate.

Therefore, as will be discussed in greater detail below, the present disclosure describes a predictive model (e.g., an asynchronous flight computer simulator) that models the flight software with actual flight computer data and not the flight computer's data transmissions, which may be used for space programs, as well as any system where data is multiplexed together (NASA, DoD, commercial space programs, etc.).

In some implementations, the present disclosure can be embodied as a method, system, or computer program product. Accordingly, in some implementations, the present disclosure can take the form of an entirely hardware implementation, an entirely software implementation (including firmware, resident software, micro-code, etc.) or an implementation combining software and hardware aspects that can all generally be referred to herein as a “circuit,” “module” or “system.” Furthermore, in some implementations, the present disclosure can take the form of a computer program product on a computer-usable storage medium having computer-usable program code embodied in the medium.

Software can include artificial intelligence systems, which can include machine learning or other computational intelligence. For example, artificial intelligence (AI) can include one or more models used for one or more problem domains. When presented with many data features, identification of a subset of features that are relevant to a problem domain can improve prediction accuracy, reduce storage space, and increase processing speed. This identification can be referred to as feature engineering. Feature engineering can be performed by users or can only be guided by users. In various implementations, a machine learning system can computationally identify relevant features, such as by performing singular value decomposition on the contributions of different features to outputs.

In some implementations, the various computing devices can include, integrate with, link to, exchange data with, be governed by, take inputs from, and/or provide outputs to one or more AI systems, which can include models, rule-based systems, expert systems, neural networks, deep learning systems, supervised learning systems, robotic process automation systems, natural language processing systems, intelligent agent systems, self-optimizing and self-organizing systems, and others. Except where context specifically indicates otherwise, references to AI, or to one or more examples of AI, should be understood to encompass one or more of these various alternative methods and systems; for example, without limitation, an AI system described for enabling any of a wide variety of functions, capabilities and solutions described herein (such as optimization, autonomous operation, prediction, control, orchestration, or the like) should be understood to be capable of implementation by operation on a model or rule set; by training on a training data set of human tag, labels, or the like; by training on a training data set of human interactions (e.g., human interactions with software interfaces or hardware systems); by training on a training data set of outcomes; by training on an AI-generated training data set (e.g., where a full training data set is generated by AI from a seed training data set); by supervised learning; by semi-supervised learning; by deep learning; or the like. For any given function or capability that is described herein, neural networks of various types can be used, including any of the types described herein, and in embodiments a hybrid set of neural networks can be selected such that within the set a neural network type that is more favorable for performing each element of a multi-function or multi-capability system or method is implemented. As one example among many, a deep learning, or black box, system can use a gated recurrent neural network for a function like language translation for an intelligent agent, where the underlying mechanisms of AI operation need not be understood as long as outcomes are favorably perceived by users, while a more transparent model or system and a simpler neural network can be used for a system for automated governance, where a greater understanding of how inputs are translated to outputs can be needed to comply with regulations or policies.

Examples of the models include recurrent neural networks (RNNs) such as long short-term memory (LSTM), deep learning models such as transformers, decision trees, support-vector machines, genetic algorithms, Bayesian networks, and regression analysis. Examples of systems based on a transformer model include bidirectional encoder representations from transformers (BERT) and generative pre-trained transformers (GPT). Training a machine-learning model can include supervised learning (for example, based on labelled input data), unsupervised learning, and reinforcement learning. In various embodiments, a machine-learning model can be pre-trained by their operator or by a third party. Problem domains include nearly any situation where structured data can be collected, and includes natural language processing (NLP), computer vision (CV), classification, image recognition, etc. Some or all of the software can run in a virtual environment rather than directly on hardware. The virtual environment can include a hypervisor, emulator, sandbox, container engine, etc. The software can be built as a virtual machine, a container, etc. Virtualized resources can be controlled using, for example, a DOCKER container platform, a pivotal cloud foundry (PCF) platform, etc. Some or all of the software can be logically partitioned into microservices. Each microservice offers a reduced subset of functionality. In various embodiments, each microservice can be scaled independently depending on load, either by devoting more resources to the microservice or by instantiating more instances of the microservice. In various embodiments, functionality offered by one or more microservices can be combined with each other and/or with other software not adhering to a microservices model.

In some implementations, any suitable computer usable or computer readable medium (or media) can be utilized. The computer readable medium can be a computer readable signal medium or a computer readable storage medium. The computer-usable, or computer-readable, storage medium (including a storage device associated with a computing device or client electronic device) can be, for example, but is not limited to, an electronic, magnetic, optical, electromagnetic, infrared, or semiconductor system, apparatus, device, or any suitable combination of the foregoing. More specific examples (a non-exhaustive list) of the computer-readable medium or storage device can include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, solid state drives (SSDs), a digital versatile disk (DVD), a Blu-ray disc, and an Ultra HD Blu-ray disc, a static random access memory (SRAM), dynamic RAM (DRAM), synchronous DRAM (SDRAM), synchronous graphics RAM (SGRAM), and video RAM (VRAM), analog magnetic tape, digital magnetic tape, rotating hard disk drive (HDDs), a memory stick, a floppy disk, a mechanically encoded device such as punch-cards or raised structures in a groove having instructions recorded thereon, a media such as those supporting the internet or an intranet, or a magnetic storage device. Note that the computer-usable or computer-readable medium could even be a suitable medium upon which the program is stored, scanned, compiled, interpreted, or otherwise processed in a suitable manner, if necessary, and then stored in a computer memory. In the context of the present disclosure, a computer-usable or computer-readable, storage medium can be any tangible medium that can contain or store a program for use by or in connection with the instruction execution system, apparatus, or device.

Examples of storage implemented by the storage hardware include a distributed ledger, such as a permissioned or permissionless blockchain. Entities recording transactions, such as in a blockchain, can reach consensus using an algorithm such as proof-of-stake, proof-of-work, and proof-of-storage. Elements of the present disclosure can be represented by or encoded as non-fungible tokens (NFTs). Ownership rights related to the non-fungible tokens can be recorded in or referenced by a distributed ledger. Transactions initialized by or relevant to the present disclosure can use one or both of fiat currency and cryptocurrencies, examples of which include bitcoin and ether.

In some implementations, a computer readable signal medium can include a propagated data signal with computer readable program code embodied therein, for example, in baseband or as part of a carrier wave. In some implementations, such a propagated signal can take any of a variety of forms, including, but not limited to, electro-magnetic, optical, or any suitable combination thereof. In some implementations, the computer readable program code can be transmitted using any appropriate medium, including but not limited to the internet, wireline, optical fiber cable, RF, etc. In some implementations, a computer readable signal medium can be any computer readable medium that is not a computer readable storage medium and that can communicate, propagate, or transport a program for use by or in connection with an instruction execution system, apparatus, or device.

In some implementations, computer program code for carrying out operations of the present disclosure can be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java®, Smalltalk, C++ or the like. Java® and all Java-based trademarks and logos are trademarks or registered trademarks of Oracle and/or its affiliates. However, the computer program code for carrying out operations of the present disclosure can also be written in conventional procedural programming languages, such as the “C” programming language, PASCAL, or similar programming languages, as well as in scripting languages such as JavaScript, PERL, or Python. The program code can execute entirely on the user's computer, partly on the user's computer, as a stand-alone software package, partly on the user's computer and partly on a remote computer or entirely on the remote computer or server. In the latter scenario, the remote computer can be connected to the user's computer through a network, such as a cellular network, local area network (LAN), a wide area network (WAN), a body area network BAN), a personal area network (PAN), a metropolitan area network (MAN), etc., or the connection can be made to an external computer (for example, through the internet using an Internet Service Provider). The networks can include one or more of point-to-point and mesh technologies. Data transmitted or received by the networking components can traverse the same or different networks. Networks can be connected to each other over a WAN or point-to-point leased lines using technologies such as Multiprotocol Label Switching (MPLS) and virtual private networks (VPNs), etc. In some implementations, electronic circuitry including, for example, programmable logic circuitry, an application specific integrated circuit (ASIC), gate arrays such as field-programmable gate arrays (FPGAs) or other hardware accelerators, micro-controller units (MCUs), or programmable logic arrays (PLAs), integrated circuits (ICs), digital circuit elements, analog circuit elements, combinational logic circuits, digital signal processors (DSPs), complex programmable logic devices (CPLDs), etc. can execute the computer readable program instructions/code by utilizing state information of the computer readable program instructions to personalize the electronic circuitry, in order to perform aspects of the present disclosure. Multiple components of the hardware can be integrated, such as on a single die, in a single package, or on a single printed circuit board or logic board. For example, multiple components of the hardware can be implemented as a system-on-chip. A component, or a set of integrated components, can be referred to as a chip, chipset, chiplet, or chip stack. Examples of a system-on-chip include a radio frequency (RF) system-on-chip, an artificial intelligence (AI) system-on-chip, a video processing system-on-chip, an organ-on-chip, a quantum algorithm system-on-chip, etc.

Examples of processing hardware can include a central processing unit (CPU), a graphics processing unit (GPU), an approximate computing processor, a quantum computing processor, a parallel computing processor, a neural network processor, a signal processor, a digital processor, a data processor, an embedded processor, a microprocessor, and a co-processor. The co-processor can provide additional processing functions and/or optimizations, such as for speed or power consumption. Examples of a co-processor include a math co-processor, a graphics co-processor, a communication co-processor, a video co-processor, and an artificial intelligence (AI) co-processor.

In some implementations, the flowchart and block diagrams in the figures illustrate the architecture, functionality, and operation of possible implementations of apparatus (systems), methods and computer program products according to various implementations of the present disclosure. Each block in the flowchart and/or block diagrams, and combinations of blocks in the flowchart and/or block diagrams, can represent a module, segment, or portion of code, which comprises one or more executable computer program instructions for implementing the specified logical function(s)/act(s). These computer program instructions can be provided to a processor of a general purpose computer, special purpose computer, or other programmable data processing apparatus to produce a machine, such that the computer program instructions, which can execute via the processor of the computer or other programmable data processing apparatus, create the ability to implement one or more of the functions/acts specified in the flowchart and/or block diagram block or blocks or combinations thereof. It should be noted that, in some implementations, the functions noted in the block(s) can occur out of the order noted in the figures (or combined or omitted). For example, two blocks shown in succession can, in fact, be executed substantially concurrently, or the blocks can sometimes be executed in the reverse order, depending upon the functionality involved.

In some implementations, these computer program instructions can also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks or combinations thereof.

In some implementations, the computer program instructions can also be loaded onto a computer or other programmable data processing apparatus to cause a series of operational steps to be performed (not necessarily in a particular order) on the computer or other programmable apparatus to produce a computer implemented process such that the instructions which execute on the computer or other programmable apparatus provide steps for implementing the functions/acts (not necessarily in a particular order) specified in the flowchart and/or block diagram block or blocks or combinations thereof.

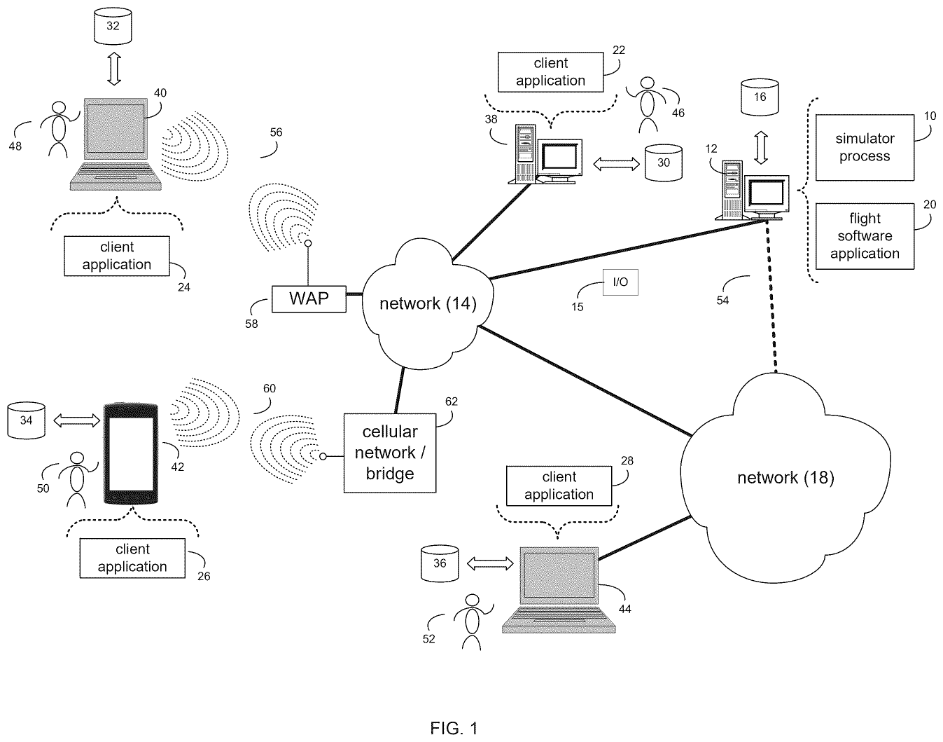

Referring now to the example implementation of FIG. 1, there is shown simulator process 10 that can reside on and can be executed by a computer (e.g., computer 12), which can be connected to a network (e.g., network 14) (e.g., the internet or a local area network). Examples of computer 12 (and/or one or more of the client electronic devices noted below) can include, but are not limited to, a storage system (e.g., a Network Attached Storage (NAS) system, a Storage Area Network (SAN)), a personal computer(s), a laptop computer(s), mobile computing device(s), a server computer, a series of server computers, a mainframe computer(s), or a computing cloud(s). A SAN can include one or more of the client electronic devices, including a RAID device and a NAS system. In some implementations, each of the aforementioned can be generally described as a computing device. In certain implementations, a computing device can be a physical or virtual device. In many implementations, a computing device can be any device capable of performing operations, such as a dedicated processor, a portion of a processor, a virtual processor, a portion of a virtual processor, portion of a virtual device, or a virtual device. In some implementations, a processor can be a physical processor or a virtual processor. In some implementations, a virtual processor can correspond to one or more parts of one or more physical processors. In some implementations, the instructions/logic can be distributed and executed across one or more processors, virtual or physical, to execute the instructions/logic. Computer 12 can execute an operating system, for example, but not limited to, Microsoft® Windows®; Mac® OS X®; Red Hat® Linux®, Windows® Mobile, Chrome OS, Blackberry OS, Fire OS, or a custom operating system. (Microsoft and Windows are registered trademarks of Microsoft Corporation in the United States, other countries or both; Mac and OS X are registered trademarks of Apple Inc. in the United States, other countries or both; Red Hat is a registered trademark of Red Hat Corporation in the United States, other countries or both; and Linux is a registered trademark of Linus Torvalds in the United States, other countries or both).

In some implementations, as will be discussed below in greater detail, a simulator process, such as simulator process 10 of FIG. 1, can identify, by a computing device, a plurality of information associated with a flight simulation. A plurality of charts for a plurality of (e.g., minor) frame arrivals can be initialized based upon, at least in part, the plurality of information associated with the flight simulation. The plurality of charts can be populated based upon, at least in part, a portion of the plurality of information associated with the flight simulation. At least a portion of the plurality of charts can be combined together. A total amount of bandwidth needed for the flight simulation can be predicted based upon, at least in part, combining together at least the portion of the plurality of charts.

In some implementations, the instruction sets and subroutines of simulator process 10, which can be stored on storage device, such as storage device 16, coupled to computer 12, can be executed by one or more processors and one or more memory architectures included within computer 12. In some implementations, storage device 16 can include but is not limited to: a hard disk drive; all forms of flash memory storage devices; a tape drive; an optical drive; a RAID array (or other array); a random access memory (RAM); a read-only memory (ROM); or combination thereof. In some implementations, storage device 16 can be organized as an extent, an extent pool, a RAID extent (e.g., an example 4D+1P R5, where the RAID extent can include, e.g., five storage device extents that can be allocated from, e.g., five different storage devices), a mapped RAID (e.g., a collection of RAID extents), or combination thereof.

In some implementations, network 14 can be connected to one or more secondary networks (e.g., network 18), examples of which can include but are not limited to: a local area network; a wide area network or other telecommunications network facility; or an intranet, for example. The phrase “telecommunications network facility,” as used herein, can refer to a facility configured to transmit, and/or receive transmissions to/from one or more mobile client electronic devices (e.g., cellphones, etc.) as well as many others.

In some implementations, computer 12 can include a data store, such as a database (e.g., relational database, object-oriented database, triplestore database, etc.), a data store, a data lake, a column store, and/or a data warehouse, and can be located within any suitable memory location, such as storage device 16 coupled to computer 12. In some implementations, data, metadata, information, etc. described throughout the present disclosure can be stored in the data store. In some implementations, computer 12 can utilize any known database management system such as, but not limited to, DB2, in order to provide multi-user access to one or more databases, such as the above noted relational database. In some implementations, the data store can also be a custom database, such as, for example, a flat file database or an XML database. In some implementations, any other form(s) of a data storage structure and/or organization can also be used. In some implementations, simulator process 10 can be a component of the data store, a standalone application that interfaces with the above noted data store and/or an applet/application that is accessed via client applications 22, 24, 26, 28. In some implementations, the above noted data store can be, in whole or in part, distributed in a cloud computing topology. In this way, computer 12 and storage device 16 can refer to multiple devices, which can also be distributed throughout the network.

In some implementations, computer 12 can execute a flight software application (e.g., flight software application 20). In some implementations, simulator process 10 and/or flight software application 20 can be accessed via one or more of client applications 22, 24, 26, 28. In some implementations, simulator process 10 can be a standalone application, or can be an applet/application/script/extension that can interact with and/or be executed within flight software application 20, a component of flight software application 20, and/or one or more of client applications 22, 24, 26, 28. In some implementations, flight software application 20 can be a standalone application, or can be an applet/application/script/extension that can interact with and/or be executed within simulator process 10, a component of simulator process 10, and/or one or more of client applications 22, 24, 26, 28. In some implementations, one or more of client applications 22, 24, 26, 28 can be a standalone application, or can be an applet/application/script/extension that can interact with and/or be executed within and/or be a component of simulator process 10 and/or flight software application 20. Examples of client applications 22, 24, 26, 28 can include, but are not limited to, e.g., a standard and/or mobile web browser, an email application (e.g., an email client application), a textual and/or a graphical user interface, a customized web browser, a plugin, an Application Programming Interface (API), or a custom application. The instruction sets and subroutines of client applications 22, 24, 26, 28, which can be stored on storage devices 30, 32, 34, 36, coupled to client electronic devices 38, 40, 42, 44, can be executed by one or more processors and one or more memory architectures incorporated into client electronic devices 38, 40, 42, 44.

In some implementations, one or more of storage devices 30, 32, 34, 36, can include but are not limited to: hard disk drives; flash drives, tape drives; optical drives; RAID arrays; random access memories (RAM); and read-only memories (ROM). Examples of client electronic devices 38, 40, 42, 44 (and/or computer 12) can include, but are not limited to, a personal computer (e.g., client electronic device 38), a laptop computer (e.g., client electronic device 40), a smart/data-enabled, cellular phone (e.g., client electronic device 42), a notebook computer (e.g., client electronic device 44), a tablet, a server, a television, a smart television, a smart speaker, an Internet of Things (IoT) device, a media (e.g., audio/video, photo, etc.) capturing and/or output device, an audio input and/or recording device (e.g., a handheld microphone, a lapel microphone, an embedded microphone (such as those embedded within eyeglasses, smart phones, tablet computers and/or watches, etc.), and a dedicated network device. Client electronic devices 38, 40, 42, 44 can each execute an operating system, examples of which can include but are not limited to, Android™, Apple® iOS®, Mac® OS X®; Red Hat® Linux®, Windows® Mobile, Chrome OS, Blackberry OS, Fire OS, or a custom operating system.

In some implementations, one or more of client applications 22, 24, 26, 28 can be configured to effectuate some or all of the functionality of simulator process 10 (and vice versa). Accordingly, in some implementations, simulator process 10 can be a purely server-side application, a purely client-side application, or a hybrid server-side/client-side application that is cooperatively executed by one or more of client applications 22, 24, 26, 28 and/or simulator process 10.

In some implementations, one or more of client applications 22, 24, 26, 28 can be configured to effectuate some or all of the functionality of flight software application 20 (and vice versa). Accordingly, in some implementations, flight software application 20 can be a purely server-side application, a purely client-side application, or a hybrid server-side/client-side application that is cooperatively executed by one or more of client applications 22, 24, 26, 28 and/or flight software application 20. As one or more of client applications 22, 24, 26, 28, simulator process 10, and flight software application 20, taken singly or in any combination, can effectuate some or all of the same functionality, any description of effectuating such functionality via one or more of client applications 22, 24, 26, 28, simulator process 10, flight software application 20, or combination thereof, and any described interaction(s) between one or more of client applications 22, 24, 26, 28, simulator process 10, flight software application 20, or combination thereof to effectuate such functionality, should be taken as an example only and not to limit the scope of the disclosure.

In some implementations, one or more of users 46, 48, 50, 52 can access computer 12 and simulator process 10 (e.g., using one or more of client electronic devices 38, 40, 42, 44) directly through network 14 or through secondary network 18. Further, computer 12 can be connected to network 14 through secondary network 18, as illustrated with phantom link line 54. Simulator process 10 can include one or more user interfaces, such as browsers and textual or graphical user interfaces, through which users 46, 48, 50, 52 can access simulator process 10.

In some implementations, the various client electronic devices can be directly or indirectly coupled to network 14 (or network 18). For example, client electronic device 38 is shown directly coupled to network 14 via a hardwired network connection. Further, client electronic device 44 is shown directly coupled to network 18 via a hardwired network connection. Client electronic device 40 is shown wirelessly coupled to network 14 via wireless communication channel 56 established between client electronic device 40 and wireless access point (i.e., WAP) 58, which is shown directly coupled to network 14. WAP 58 can be, for example, an IEEE 802.11a, 802.11b, 802.11g, 802.11n, 802.11ac, Wi-Fi®, RFID, and/or Bluetooth™ (including Bluetooth™ Low Energy) or any device that is capable of establishing wireless communication channel 56 between client electronic device 40 and WAP 58. Client electronic device 42 is shown wirelessly coupled to network 14 via wireless communication channel 60 established between client electronic device 42 and cellular network/bridge 62, which is shown by example directly coupled to network 14.

In some implementations, some or all of the IEEE 802.11x specifications can use Ethernet protocol and carrier sense multiple access with collision avoidance (i.e., CSMA/CA) for path sharing. The various 802.11x specifications can use phase-shift keying (i.e., PSK) modulation or complementary code keying (i.e., CCK) modulation, for example. Bluetooth™ (including Bluetooth™ Low Energy) is a telecommunications industry specification that allows, e.g., mobile phones, computers, smart phones, and other electronic devices to be interconnected using a short-range wireless connection. Other forms of interconnection (e.g., Near Field Communication (NFC)) can also be used. In some implementations, computer 12 can be directed or controlled by an operator. Computer 12 can be hosted by one or more of assets owned by the operator, assets leased by the operator, and third-party assets. The assets can be referred to as a private, community, or hybrid cloud computing network or cloud computing environment. For example, computer 12 can be partially or fully hosted by a third party offering software as a service (SaaS), platform as a service (PaaS), and/or infrastructure as a service (IaaS). Computer 12 can be implemented using agile development and operations (DevOps) principles. In some implementations, some or all of computer 12 can be implemented in a multiple-environment architecture. For example, the multiple environments can include one or more production environments, one or more integration environments, one or more development environments, etc.

In some implementations, various I/O requests (e.g., I/O request 15) can be sent from, e.g., client applications 22, 24, 26, 28 to, e.g., computer 12 (and vice versa). Examples of I/O request 15 can include but are not limited to, data write requests (e.g., a request that content be written to computer 12) and data read requests (e.g., a request that content be read from computer 12).

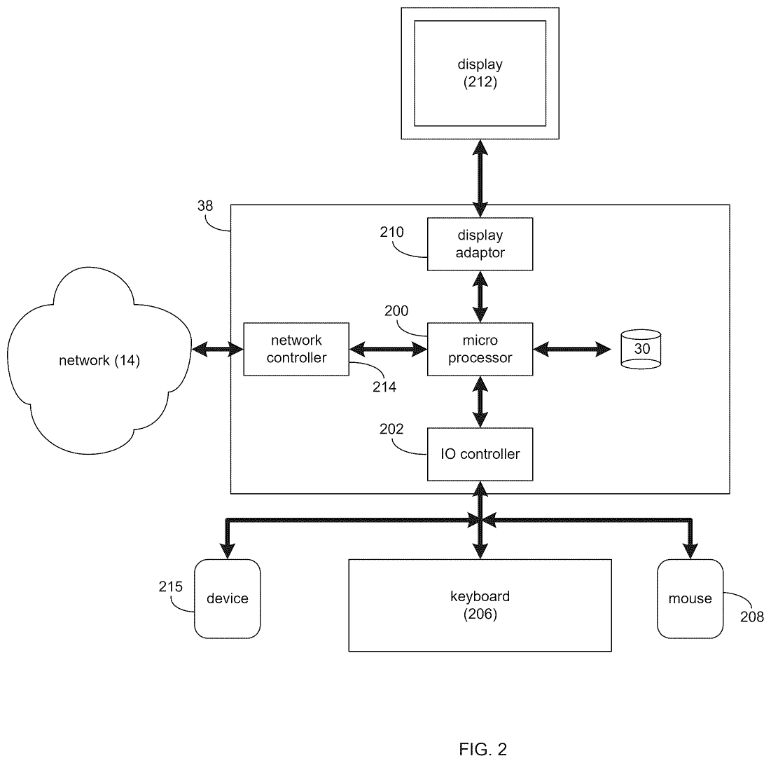

Referring also to the example implementation of FIG. 2, there is shown a diagrammatic view of client electronic device 38. While client electronic device 38 is shown in this figure, this is for example purposes only and is not intended to be a limitation of this disclosure, as other configurations are possible. Additionally, any computing device capable of executing, in whole or in part, simulator process 10 can be substituted for client electronic device 38 (in whole or in part) within FIG. 2, examples of which can include but are not limited to computer 12 and/or one or more of client electronic devices 38, 40, 42, 44.

In some implementations, client electronic device 38 can include a processor (e.g., microprocessor 200) configured to, e.g., process data and execute the above-noted code/instruction sets and subroutines. Microprocessor 200 can be coupled via a storage adaptor to the above-noted storage device(s) (e.g., storage device 30). An I/O controller (e.g., I/O controller 202) can be configured to couple microprocessor 200 with various devices (e.g., via wired or wireless connection), such as keyboard 206, pointing/selecting device (e.g., touchpad, touchscreen, mouse 208, etc.), custom device (e.g., device 215), USB ports, and printer ports. A display adaptor (e.g., display adaptor 210) can be configured to couple display 212 (e.g., touchscreen monitor(s), plasma, CRT, or LCD monitor(s), etc.) with microprocessor 200, while network controller/adaptor 214 (e.g., an Ethernet adaptor) can be configured to couple microprocessor 200 to the above-noted network 14 (e.g., the Internet or a local area network).

As will be discussed below, simulator process 10 can at least help, e.g., improve data flight (or other) simulation technology, necessarily rooted in computer technology in order to overcome an example and non-limiting problem specifically arising in the realm of computer processing and to improve existing technological processes associated with, e.g., flight simulation. It will be appreciated that the computer processes described throughout are integrated into one or more practical applications, and when taken at least as a whole are not considered to be well-understood, routine, and conventional functions.

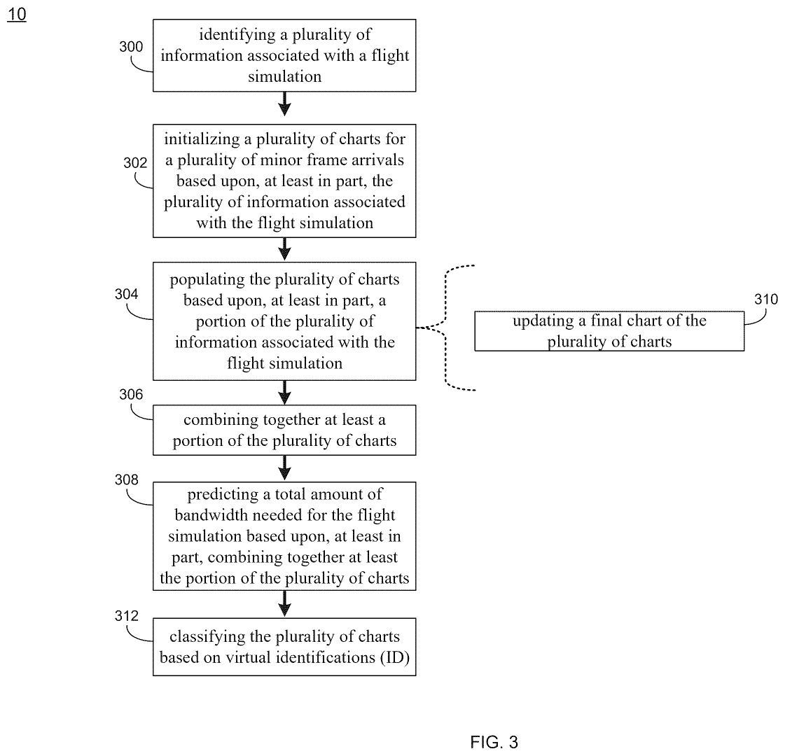

As discussed above and referring also at least to the example implementations of FIG. 3, simulator process 10 can identify 300, by a computing device, a plurality of information associated with a flight simulation. Simulator process 10 can initialize 302 a plurality of charts for a plurality of (e.g., minor) frame arrivals based upon, at least in part, the plurality of information associated with the flight simulation. Simulator process 10 can populate 304 the plurality of charts based upon, at least in part, a portion of the plurality of information associated with the flight simulation. Simulator process 10 can combine 306 together at least a portion of the plurality of charts. Simulator process 10 can predict 308 a total amount of bandwidth needed for the flight simulation based upon, at least in part, combining together at least the portion of the plurality of charts.

In some implementations, simulator process 10 can identify 300, by a computing device, a plurality of information associated with a flight simulation. For instance, in some implementations, the plurality of information (e.g., flight software input information) associated with the flight simulation can include at least one of content ID, (e.g., minor) frame length, frequency of occurrence, description, (e.g., minor) frame starting, and virtual channel ID. Generally, content ID is an identification number, for example, ID number 1600 tells us where this data is coming from, and can be a unique number only assigned to that particular data. Frequency is how often this ID happens in a certain period of time (e.g., 1 second, e.g., 50 Hz means it happens in every (minor) frame (50 out of 50 minor frame), 25 Hz means it happens every other minor frame, and so on. Each ID number can have a message size (e.g., minor frame size/length or just message size); e.g., if ID 1600 has a frequency of 50 Hz, with a size of 2 k bits, one will see that ID every minor frame with 2 k bits of data (message size). VC ID is like a flag that tells you if you can multiplex certain data together back to back in a packet. So, for example, if there are 2 different VC ID, each packet might only contain that VC ID. Packets VC1 and 2 are separate, which may be beneficial in designing an efficient system.

In some implementations, simulator process 10 can construct a plurality of (e.g., minor) frame arrivals based upon, at least in part, the plurality of information associated with the flight simulation, where, in some implementations, each minor frame arrival of the plurality of minor frame arrivals can be constructed per input window size time. For instance, upon receiving (or otherwise identifying or obtaining) the data rates, word geometry, and formats, simulator process 10 may (e.g., via an asynchronous function) construct a minor frame arrival per each WST. The construction of the minor frame arrival is a time allotted window where transmitted data can be processed. As an example, one minor frame is the minor frame word size times the word length (e.g., 800×12=9600). The system may model how many of the minor frames will arrive per WST based on their data rates.

In some implementations, simulator process 10 can initialize 302 a plurality of charts for a plurality of minor frame arrivals based upon, at least in part, the plurality of information associated with the flight simulation. For instance, simulator process 10 may initializing the charts (e.g., histograms) for minor frames (note in this non-limiting example that the total number of frames is 1/(processing time), e.g., 1/0.02 s=50 minor frame spots, where each spot represents, e.g., 20 ms in this example. In some implementations, the plurality of charts can include bits per minor frame and in some implementations, the plurality of charts can include a number of message identifier headers per minor frame. As explained above, each time there is a message from a unique Identifier number, there is a message size. In addition, the telemetry unit of simulator process 10 can add additional identifier overhead to that, so assume for example purposes only that there are 50 unique IDs in one minor frame, there is additional 50*message identifier header overhead size, e.g., 50*20 bytes=1000 bytes per minor frame.

In some implementations, at least some of the portion of the plurality of information associated with the flight simulation may be simulated by simulator process 10 using an actual load used for a flight when one or more portions of the plurality of information associated with the flight simulation is unavailable. For instance, there may be situations where there are hardware limitations and drawbacks within a test, for example, the test configuration is a subset of the actual configuration (e.g., the test can only configure half of the bandwidth that is used for an actual flight). This may cause issues, because in this case, it may not be possible for simulator process 10 to test the actual loads used for flights. As a result, the overall bandwidth analysis using the test might be less than what the actual bandwidth would be for the flight. To mitigate that risk, simulator process 10 may be used as a simulator given the actual polarity of inputs (e.g., geometry of inputs to the model). As a result, the inputs are now matching the actual load that is used for the flight and not the loads used for the test, which is subset of the actual loads. Simulator process 10 solves this example and non-limiting issue by predicting the actual telemetry bandwidth for the hardware/software modules that were not able to be configured like the flights. Once the test is done, simulator process 10 can be used to correct the test result by the Telemetry Correction Logic (TCL). Once corrected, the final output is the result to be evaluated for the actual flight. For example, if the test shows 16 Mbps of overall data, and the final prediction using simulator process 10 and correction using TCL is 18 Mbps, the 18 Mbps may be used to evaluate if the bandwidth requirement may be met or not.

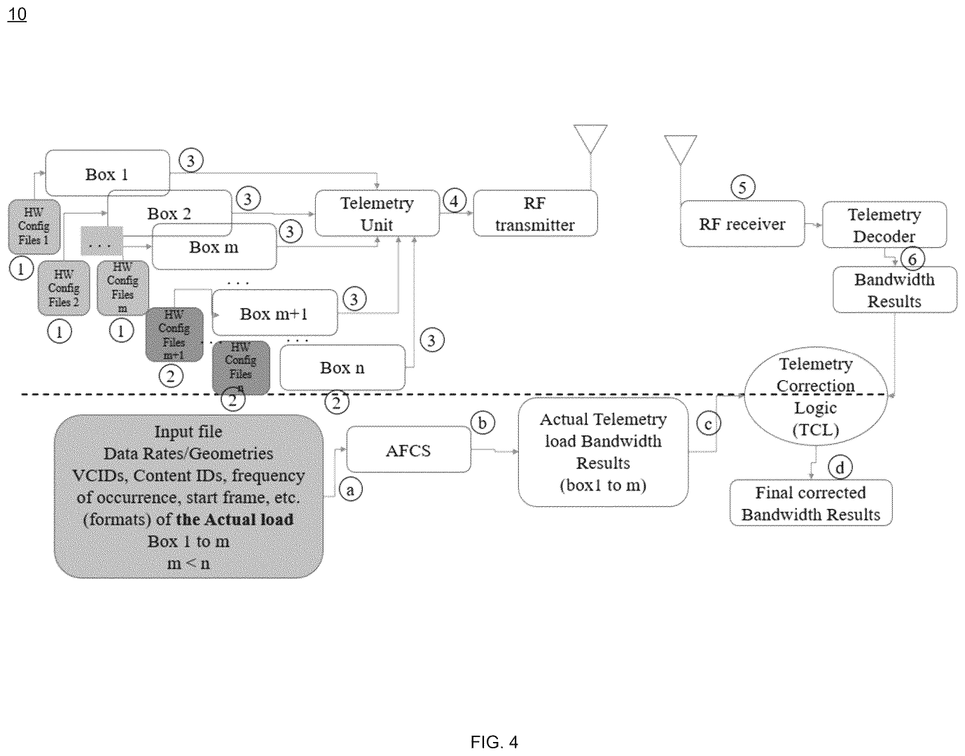

For instance, and referring at least to the example implementation of FIG. 4, an alternative view of a flowchart of simulation process 10 is shown. At step 1, there is shown a fixed hardware configuration that is a subset of the actual load due to unavailability. At step 2, there is shown a fixed hardware configuration with the actual load. At step 3, programmed data rates and geometry are telemetered by each box (e.g., via simulation process 10). At step 4, the telemetry unit (e.g., via simulation process 10) multiplexes all telemetry from each box and sends it to the RF Transmitter. At step 5, simulation process 10 transmits the data to ground. At step 6, simulation process 10 decodes the data that is to be corrected by Telemetry Correction Logic (TCL) (e.g., via simulation process 10).

At step a., Input file, Data Rates/Geometries, VCIDs, Content IDs, frequency of occurrence, start frame, etc. (formats) of the actual load for Box 1 to m, m<n. At step b., the actual telemetry load Bandwidth Results (box1 to m). At step c., the bandwidth result is inputted to the TCL. At step d., the final corrected bandwidth results are provided.

As will be discussed in further detail below, in some implementations, for each content ID, simulator process 10 can read the virtual channel ID, frequency of occurrence, starting minor frame, and length of the message identifier header; populate the charts, and update final charts. For example, in some implementations, simulator process 10 can populate 304 the plurality of charts based upon, at least in part, a portion of the plurality of information associated with the flight simulation. The charts can be populated with the overall data per minor frame. For example, if the frequency is 50 Hz, the starting frame is 1, and that implies that the content of data will occur in every minor frame with that length of message. As a result, simulator process 10 can populate the chart for that content ID given the information. In the example, since the frequency is 50 Hz, all the minor frame spots are filled with the same amount of data. If frequency is 25 Hz, that means data can be distributed 25 times, and the starting frame is either at frame 1 or 2, simulator process 10 can distribute every other frame with data, and so on. Frequency information can be different and varies from 1 to 50 (in some implementations) for each content ID. Simulator process 10 has the logic that can distribute based on the frequency input and starting frame.

In some implementations, populating the plurality of charts can include updating 310 a final chart of the plurality of charts, and in some implementations, at least a portion of the plurality of charts can be updated for each content ID. For instance, for each content ID, the charts can be populated, but also a final chart needs to be updated each time as well. For example, in each iteration, simulator process 10 can go through each unique ID, and populate the entire minor frames based on their message size. Thus, simulator process 10 can keep an array of histograms (or other chart type) for each iteration. Each time, simulator process 10 can go through another iteration that histogram will be update with new updated data. For example, if in iteration one the system adds 2 k bits for every minor frame (at 50 Hz), and next ID has message size 1K at 50 Hz, then the updated one will have 3K bits of data every minor frame in the example. Now, if this was at 25 Hz, then either the odd ones or the even ones will have 3 K of data as updated histogram. Note, the starting frame in our model is important to know. Then 25 Hz can have a starting frame at 1 or 2. Let's say it is at 1, then simulator process 10 populates frames 1, 3, 5, 7, . . . , 49. If the starting frame is at 2, then simulator process 10 can populate at 2, 4, 6, . . . , 50. Advantageously, in some implementations, simulator process 10 can be used to make the distributed more uniform by changing the frequencies, size of the message, and starting minor frames. Similarly, other charts (e.g., histograms) can be used for message identifier header counts. Each time there is a message identifier header message from a Content ID, there is an extra message identifier header for each message.

In some implementations, simulator process 10 can combine 306 together at least a portion of the plurality of charts. For example, the overall predicted data and message identifier header—once the two main charts are distributed fully, and simulator process 10 has gone through all the content IDs, simulator process 10 can then add all the charts distributed for data to determine the overall data. Simulator process 10 can also add all the message identifier header charts and determine the overall message identifier headers.

In some implementations, simulator process 10 can classify 312 the plurality of charts based on virtual identifications (ID). For instance, simulator process 10 can also classify the charts based on Virtual (Channel) IDs, since data of different VC IDs might not be packetized in the same packet. For example, all the VC_ID=2 can be packetized back to back, then the fill data can be inserted, then a new ENCAP can be used for VC_ID=3. ENCAP is using CCSDS standard, which may generally be described with other protocols as the identifier of the beginning of a packet or the like. As a non-limiting advantage, simulator process 10 can thus go beyond just predicting the overall data and message identifier header, and also predict the overhead added by the particular protocol used.

In some implementations, simulator process 10 can predict 308 a total amount of bandwidth needed for the flight simulation based upon, at least in part, combining together at least the portion of the plurality of charts. For instance, in some implementations, the total amount of bandwidth needed for the flight simulation can include at least one of an overall raw data, an overall data, an overhead data, and a filled data. For instance, for the overall raw data (e.g., excluding message identifier header), simulator process 10 can predict all the raw data and break them down into different type of data (e.g., CS data, booster data, etc.). Overall data may generally be all the data, including all the overhead mentioned above. Overhead data may include the CCSDS overhead, including message identifier header and ENCAP header, and filled data. Filled data can be used to fill the rest of the packet and can be included in the overall overhead.

Thus, simulator process 10 can populate minor frames with exact data using the flight software, and can separate chart (e.g., histogram) distribution based on Virtual Channel IDs, which can be beneficial when packetizing using certain protocols, can predict overhead using, e.g., CCSDS, filled data, message identifier header for each VC ID, etc. Note that in some implementations, each VC ID can start in a new packet, therefore, fill data can be important in determining data rates, geometry and distribution of VC IDs. In some implementations, if minor frame distribution is not given or ready, simulator process 10 can allow distribution based on frequency and predict overall data in the meantime, which implies, simulator process 10 can be used to design an efficient OFI system ahead of any testing, which may be valuable in developing geometry and minor frame distribution of data.

Clause 1. A computer-implemented method comprising: identifying, by a computing device, a plurality of information associated with a flight simulation; initializing a plurality of charts for a plurality of frame arrivals based upon, at least in part, the plurality of information associated with the flight simulation; populating the plurality of charts based upon, at least in part, a portion of the plurality of information associated with the flight simulation; combining together at least a portion of the plurality of charts; and predicting a total amount of bandwidth needed for the flight simulation based upon, at least in part, combining together at least the portion of the plurality of charts.

Clause 2. The computer-implemented method of clause 1, wherein populating the plurality of charts includes updating a final chart of the plurality of charts.

Clause 3. The computer-implemented method of clause 1, wherein at least some of the portion of the plurality of information associated with the flight simulation is simulated using an actual load used for a flight when one or more portions of the plurality of information associated with the flight simulation is unavailable.

Clause 4. The computer-implemented method of clause 1, wherein the plurality of charts includes a number of message identifier headers per frame.

Clause 5. The computer-implemented method of clause 1 further comprising classifying the plurality of charts based on virtual identifications (ID).

Clause 6. The computer-implemented method of clause 2, wherein the plurality of information associated with the flight simulation includes content ID, frame length, frequency of occurrence, description, frame starting, virtual channel ID, or combinations thereof.

Clause 7. The computer-implemented method of clause 6, wherein at least a portion of the plurality of charts are updated for each content ID.

Clause 8. A computer program product residing on a computer readable storage medium having a plurality of instructions stored thereon which, when executed across one or more processors, causes at least a portion of the one or more processors to perform operations comprising: identifying a plurality of information associated with a flight simulation; initializing a plurality of charts for a plurality of frame arrivals based upon, at least in part, the plurality of information associated with the flight simulation; populating the plurality of charts based upon, at least in part, a portion of the plurality of information associated with the flight simulation; combining together at least a portion of the plurality of charts; and predicting a total amount of bandwidth needed for the flight simulation based upon, at least in part, combining together at least the portion of the plurality of charts.

Clause 9. The computer-implemented method of clause 8, wherein populating the plurality of charts includes updating a final chart of the plurality of charts.

Clause 10. The computer-implemented method of clause 8, wherein at least some of the portion of the plurality of information associated with the flight simulation is simulated using an actual load used for a flight when one or more portions of the plurality of information associated with the flight simulation is unavailable.

Clause 11. The computer-implemented method of clause 8, wherein the plurality of charts includes a number of message identifier headers per frame.

Clause 12. The computer-implemented method of clause 8, wherein the

operations further comprise classifying the plurality of charts based on virtual identifications (ID).

Clause 13. The computer-implemented method of clause 9, wherein the plurality of information associated with the flight simulation includes content ID, frame length, frequency of occurrence, description, frame starting, virtual channel ID, or combinations thereof.

Clause 14. The computer-implemented method of clause 13, wherein at least a portion of the plurality of charts are updated for each content ID.

Clause 15. A computing system including one or more processors and one or more memories configured to perform operations comprising: identifying a plurality of information associated with a flight simulation; initializing a plurality of charts for a plurality of frame arrivals based upon, at least in part, the plurality of information associated with the flight simulation; populating the plurality of charts based upon, at least in part, a portion of the plurality of information associated with the flight simulation; combining together at least a portion of the plurality of charts; and predicting a total amount of bandwidth needed for the flight simulation based upon, at least in part, combining together at least the portion of the plurality of charts.

Clause 16. The computer-implemented method of clause 15, wherein populating the plurality of charts includes updating a final chart of the plurality of charts.

Clause 17. The computer-implemented method of clause 15, wherein the plurality of charts includes a bits per frame and a number of message identifier headers per frame.

Clause 18. The computer-implemented method of clause 15, wherein the operations further comprise classifying the plurality of charts based on virtual identifications (ID).

Clause 19. The computer-implemented method of clause 16, wherein the plurality of information associated with the flight simulation includes content ID, frame length, frequency of occurrence, description, frame starting, virtual channel ID, or combinations thereof.

Clause 20. The computer-implemented method of clause 15, wherein at least some of the portion of the plurality of information associated with the flight simulation is simulated using an actual load used for a flight when one or more portions of the plurality of information associated with the flight simulation is unavailable.

The terminology used herein is for the purpose of describing particular implementations only and is not intended to be limiting of the disclosure. As used herein, the singular forms “a”, “an” and “the” are intended to include the plural forms as well, including any steps performed by a/the computer/processor, unless the context clearly indicates otherwise. As used herein, the phrase “at least one of A, B, and C” should be construed to mean a logical (A OR B OR C), using a non-exclusive logical OR, and should not be construed to mean “at least one of A, at least one of B, and at least one of C.” As another example, the language “at least one of A and B” (and the like) as well as “at least one of A or B” (and the like) should be interpreted as covering only A, only B, or both A and B, unless the context clearly indicates otherwise. It will be further understood that the terms “comprises” and/or “comprising,” when used in this specification, specify the presence of stated features, integers, steps (not necessarily in a particular order), operations, elements, and/or components, but do not preclude the presence or addition of one or more other features, integers, steps (not necessarily in a particular order), operations, elements, components, and/or groups thereof. Example sizes/models/values/ranges can have been given, although examples are not limited to the same.

The terms (and those similar to) “coupled,” “attached,” “connected,” “adjoining,” “transmitting,” “receiving,” “connected,” “engaged,” “coupled,” “adjacent,” “next to,” “on top of,” “above,” “below,” “abutting,” and “disposed,” used herein is to refer to any type of relationship, direct or indirect, between the components in question, and is to apply to electrical, mechanical, fluid, optical, electromagnetic, electromechanical, or other connections. Additionally, the terms “first,” “second,” etc. are used herein only to facilitate discussion, and carry no particular temporal or chronological significance unless otherwise indicated. The terms “cause” or “causing” means to make, force, compel, direct, command, instruct, and/or enable an event or action to occur or at least be in a state where such event or action is to occur, either in a direct or indirect manner. The term “set” does not necessarily exclude the empty set-in other words, in some circumstances a “set” can have zero elements. The term “non-empty set” can be used to indicate exclusion of the empty set-that is, a non-empty set must have one or more elements, but this term need not be specifically used. The term “subset” does not necessarily require a proper subset. In other words, a “subset” of a first set can be coextensive with (equal to) the first set. Further, the term “subset” does not necessarily exclude the empty set—in some circumstances a “subset” can have zero elements.

The corresponding structures, materials, acts, and equivalents (e.g., of all means or step plus function elements) that can be in the claims below are intended to include any structure, material, or act for performing the function in combination with other claimed elements as specifically claimed. While the disclosure describes structures corresponding to claimed elements, those elements do not necessarily invoke a means plus function interpretation unless they explicitly use the signifier “means for.” Unless otherwise indicated, recitations of ranges of values are merely intended to serve as a shorthand way of referring individually to each separate value falling within the range, and each separate value is hereby incorporated into the specification as if it were individually recited. While the drawings divide elements of the disclosure into different functional blocks or action blocks, these divisions are for illustration only. According to the principles of the present disclosure, functionality can be combined in other ways such that some or all functionality from multiple separately-depicted blocks can be implemented in a single functional block; similarly, functionality depicted in a single block can be separated into multiple blocks. Unless explicitly stated as mutually exclusive, features depicted in different drawings can be combined consistent with the principles of the present disclosure.

The description of the present disclosure has been presented for purposes of illustration and description but is not intended to be exhaustive or limited to the disclosure in the form disclosed. After reading the present disclosure, many modifications, variations, substitutions, and any combinations thereof will be apparent to those of ordinary skill in the art without departing from the scope and spirit of the disclosure. The implementation(s) were chosen and described in order to explain the principles of the disclosure and the practical application, and to enable others of ordinary skill in the art to understand the disclosure for various implementation(s) with various modifications and/or any combinations of implementation(s) as are suited to the particular use contemplated. The features of any dependent claim can be combined with the features of any of the independent claims or other dependent claims.

Having thus described the disclosure of the present application in detail and by reference to implementation(s) thereof, it will be apparent that modifications, variations, and any combinations of implementation(s) (including any modifications, variations, substitutions, and combinations thereof) are possible without departing from the scope of the disclosure defined in the appended claims.

What is claimed is:

1. A computer-implemented method comprising:
identifying, by a computing device, a plurality of information associated with a flight simulation;
initializing a plurality of charts for a plurality of frame arrivals based upon, at least in part, the plurality of information associated with the flight simulation;
populating the plurality of charts based upon, at least in part, a portion of the plurality of information associated with the flight simulation;
combining together at least a portion of the plurality of charts; and
predicting a total amount of bandwidth needed for the flight simulation based upon, at least in part, the combining together at least the portion of the plurality of charts.

2. The computer-implemented method of claim 1, wherein populating the plurality of charts includes updating a final chart of the plurality of charts.

3. The computer-implemented method of claim 1, wherein at least some of the portion of the plurality of information associated with the flight simulation is simulated using an actual load used for a flight when one or more portions of the plurality of information associated with the flight simulation is unavailable.

4. The computer-implemented method of claim 1, wherein the plurality of charts includes a number of message identifier headers per frame.

5. The computer-implemented method of claim 1 further comprising classifying the plurality of charts based on virtual identifications (ID).

6. The computer-implemented method of claim 2, wherein the plurality of information associated with the flight simulation includes content ID, frame length, frequency of occurrence, description, frame starting, virtual channel ID, or combinations thereof.

7. The computer-implemented method of claim 6, wherein at least a portion of the plurality of charts are updated for each content ID.

8. A computer program product residing on a computer readable storage medium having a plurality of instructions stored thereon which, when executed across one or more processors, causes at least a portion of the one or more processors to perform operations comprising:
identifying a plurality of information associated with a flight simulation;
initializing a plurality of charts for a plurality of frame arrivals based upon, at least in part, the plurality of information associated with the flight simulation;
populating the plurality of charts based upon, at least in part, a portion of the plurality of information associated with the flight simulation;
combining together at least a portion of the plurality of charts; and
predicting a total amount of bandwidth needed for the flight simulation based upon, at least in part, the combining together at least the portion of the plurality of charts.

9. The computer program product of claim 8, wherein populating the plurality of charts includes updating a final chart of the plurality of charts.

10. The computer program product of claim 8, wherein at least some of the portion of the plurality of information associated with the flight simulation is simulated using an actual load used for a flight when one or more portions of the plurality of information associated with the flight simulation is unavailable.

11. The computer program product of claim 8, wherein the plurality of charts includes a number of message identifier headers per frame.

12. The computer program product of claim 8, wherein the operations further comprise classifying the plurality of charts based on virtual identifications (ID).

13. The computer program product of claim 9, wherein the plurality of information associated with the flight simulation includes content ID, frame length, frequency of occurrence, description, frame starting, virtual channel ID, or combinations thereof.

14. The computer program product of claim 13, wherein at least a portion of the plurality of charts are updated for each content ID.

15. A computing system including one or more processors and one or more memories configured to perform operations comprising:
identifying a plurality of information associated with a flight simulation;
initializing a plurality of charts for a plurality of frame arrivals based upon, at least in part, the plurality of information associated with the flight simulation;
populating the plurality of charts based upon, at least in part, a portion of the plurality of information associated with the flight simulation;
combining together at least a portion of the plurality of charts; and
predicting a total amount of bandwidth needed for the flight simulation based upon, at least in part, the combining together at least the portion of the plurality of charts.

16. The computing system of claim 15, wherein populating the plurality of charts includes updating a final chart of the plurality of charts.

17. The computing system of claim 15, wherein the plurality of charts includes a bits per frame and a number of message identifier headers per frame.

18. The computing system of claim 15, wherein the operations further comprise classifying the plurality of charts based on virtual identifications (ID).

19. The computing system of claim 16, wherein the plurality of information associated with the flight simulation includes content ID, frame length, frequency of occurrence, description, frame starting, virtual channel ID, or combinations thereof.

20. The computing system of claim 15, wherein at least some of the portion of the plurality of information associated with the flight simulation is simulated using an actual load used for a flight when one or more portions of the plurality of information associated with the flight simulation is unavailable.
